(19) United States
(12) Patent Application Publication
(10) Pub. No.: US 2026/0190808 A1
(43) Pub. Date: Jul. 2, 2026

(54) DISPLAY PANEL

(71) Applicant: LG Display Co., Ltd., Seoul (KR)

(72) Inventors: So Young JANG, Paju-si (KR); Hee Cheol KIM, Paju-si (KR)

(73) Assignee: LG Display Co., Ltd., Seoul (KR)

(21) Appl. No.: 19/308,937

(22) Filed: Aug. 25, 2025

(30) Foreign Application Priority Data
Dec. 30, 2024 (KR) 10-2024-0200904

(51) Int. Cl. H10K 59/80; H10K 59/122; H10K 59/38

(52) U.S. Cl. CPC H10K 59/879; H10K 59/122; H10K 59/38; H10K 59/8792

(57) ABSTRACT

A display panel is disclosed. The display panel includes a substrate, a light emitting element disposed over the substrate, a black matrix defining an opening corresponding to the light emitting element, a first lens disposed in the opening, a color filter disposed on the first lens in the opening, a second lens disposed on the color filter, and a high refractive index layer disposed on the second lens. A refractive index of the first lens is higher than a refractive index of the second lens. A refractive index of the high refractive index layer is higher than the refractive index of the second lens.

This application claims the benefit of Korean Patent Application No. 10-2024-0200904, filed on Dec. 30, 2024, which is hereby incorporated by reference as if fully set forth herein.

### BACKGROUND

### Field of the Disclosure

The present disclosure relates to a display panel.

### Discussion of the Related Art

In accordance with advances in information technology, the market for display devices, which are connection media between users and information, is expanding. Accordingly, use of display devices such as light emitting display (LED) devices, quantum dot display (QDD) devices, liquid crystal display (LCD) devices, etc. is increasing.

Such display devices mentioned above include a display panel including sub-pixels, a driver configured to output drive signals for driving of the display panel, and a power supply configured to generate a drive voltage to be supplied to the display panel or the driver, etc.

In such display devices mentioned above, when drive signals, for example, a scan signal, a data signal, etc., are supplied to the sub-pixels formed at the display panel, selected ones of the sub-pixels transmit light therethrough or directly emit light and, as such, an image may be displayed.

Meanwhile, when such a display device expresses an image, external light may be reflected by an electrode, etc., constituting each pixel of the display panel, thereby disrupting the viewing experience.

In recent years, active research has been conducted in order to reduce reflectance of external light as mentioned above.

### SUMMARY

Accordingly, the present disclosure is directed to a display panel that substantially obviates one or more problems due to limitations and disadvantages of the related art.

It is an object of the present disclosure to provide a display panel capable of reducing reflectance of external light.

Objects of the present disclosure are not limited to the above-described object, and other objects of the present disclosure not yet described will be more clearly understood by those skilled in the art from the following detailed description.

To achieve these objects and other advantages and in accordance with the purpose of the disclosure, as embodied and broadly described herein, a display panel includes a substrate with a plurality sub-pixels disposed on an active area, a black matrix disposed on the plurality of sub-pixels, a first lens disposed in openings of the black matrix, a color filter disposed on the first lens in the openings of the black matrix, a second lens disposed on the color filter, and a high refractive index layer disposed on the second lens, wherein a refractive index of the first lens is higher than a refractive index of the second lens, and wherein a refractive index of the high refractive index layer is higher than the refractive index of the second lens.

The refractive index difference between the first lens and the color filter may be greater than the refractive index difference between the second lens and the color filter.

The refractive index difference between the high refractive index layer and the second lens may be greater than the refractive index difference between the second lens and the color filter.

The refractive index of the second lens may be equal to the refractive index of the color filter.

The width of the second lens may be greater than the width of the first lens.

The width of the second lens may be greater than the width of each opening of the black matrix.

The distance among portions of the bank partitioning the plurality of sub-pixels from one another may be smaller than the width of each opening of the black matrix.

The bank may include a light absorption material.

The width of the bank may be greater than the width of the black matrix.

The radius of curvature of the second lens may be greater than the radius of curvature of the first lens.

The maximum height of the second lens may be greater than the maximum height of the first lens.

The black matrix and the first lens may be disposed on an optical layer disposed on the plurality of sub-pixels. The refractive index of the optical layer may be lower than the refractive index of the first lens.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and along with the description serve to explain various principles of the present disclosure. In the drawings:

FIG. 1 is a configuration diagram explaining the concept of the configuration of a display device according to example embodiments of the present disclosure;

FIG. 2 shows circuit diagrams explaining an example of an equivalent pixel circuit applicable to a display panel according to example embodiments of the present disclosure;

FIG. 3 is a cross-sectional view explaining an example of a cross-sectional structure applied to the display panel according to example embodiments of the present disclosure;

FIG. 4 is a cross-sectional view explaining structures of first and second lenses of each sub-pixel shown in FIG. 3 in more detail; and

FIG. 5 shows cross-sectional views explaining effects of the first and second lenses applied to example embodiments the present disclosure.

### DETAILED DESCRIPTION

Hereinafter, various example embodiments of the present disclosure will be described in more detail with reference to the accompanying drawings.

Throughout the present disclosure, the same reference numerals designate the same constituent elements, respectively. Thicknesses, ratios, and dimensions, etc. of constituent elements may be exaggerated in a part of the drawings, for effective description thereof. The dimensions and scales of constituent elements shown in the drawings may be different from actual dimensions and scales, for convenience of description, and, as such, should not be interpreted to be the same as those shown in the drawings.

It should be understood that, when a constituent element (or a region, a layer, a portion or the like) is referred to as being “on”, “connected to”, or “coupled to” another element, it may be directly on, connected or coupled to the other element, or an intervening third element may be present.

The term “and/or” used herein includes any and all combinations of one or more of configurations associated with one another.

Although terms including an ordinal number, such as first or second, may be used to describe a variety of constituent elements, the constituent elements are not limited to the terms, and the terms are used only for the purpose of discriminating one constituent element from other constituent elements. For example, a first constituent element may be referred to as a second constituent element within the scope of the present disclosure. Similarly, the second constituent element may be referred to as the first constituent element. A component described in a singular form encompasses components in a plural form, and vice versa, unless particularly stated otherwise.

Terms such as “under”, “below”, “over”, and “above” may be used to explain associated relations of configurations shown in the drawings. The terms are relative concepts and are described with reference to directions indicated in the drawings. For example, at least one intervening element may be present between two elements unless “immediately” or “directly” is used. It should be understood that terms, such as “below”, “beneath”, “lower”, “above”, “upper”, etc., which are spatially-relative terms, may be used to easily explain associated relations of one device or constituent element with another device or other constituent elements. Accordingly, for example, “below” or “lower” with reference to a first constituent element may encompass a direction opposite to above or upper with reference to the first constituent element.

It should be understood that spatially-relative terms are intended to encompass different orientations of a device when the device is used or operates, in addition to the orientation depicted in the drawings. For example, if a device in one of the drawings is turned over, elements described as being disposed “below” or “beneath” other elements would then be disposed “above” the other elements. The exemplary terms “below” or “beneath” can, therefore, encompass both an orientation of above and below.

It should be understood that the term “comprising”, “including”, or the like is intended to express the existence of characteristics, numerals, steps, operations, constituent elements, parts, or a combination thereof, and does not exclude one or more other characteristics, numerals, steps, operations, constituent elements, parts, or combinations thereof, or any addition thereto.

The respective features of various embodiments according to the present disclosure can be partially or entirely joined or combined and technically variably related or operated, and the embodiments can be implemented independently or in combination.

Hereinafter, a display device according to various example embodiments of the present disclosure will be described in more detail with reference to the accompanying drawings and embodiments.

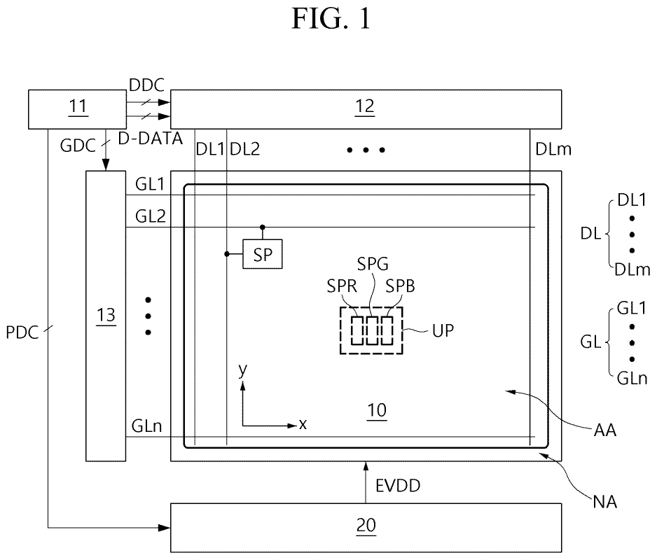

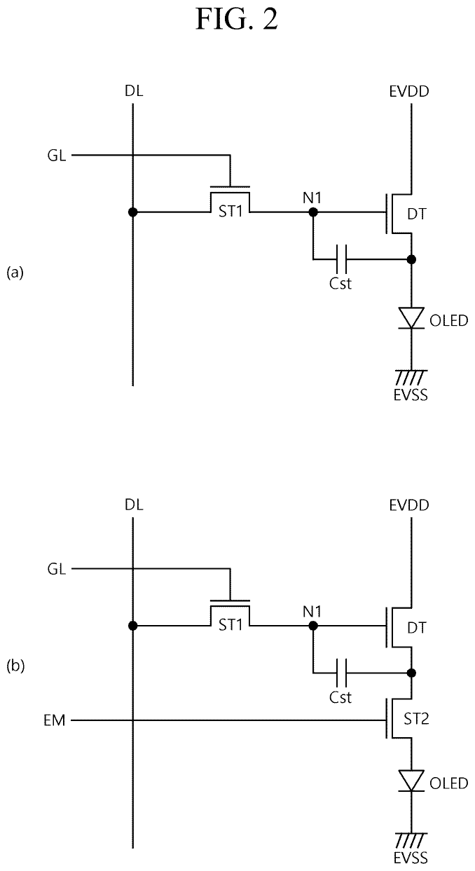

FIG. 1 is a configuration diagram explaining the concept of the configuration of a display device according to example embodiments of the present disclosure. FIG. 2 shows circuit diagrams explaining an example of an equivalent pixel circuit applicable to a display panel according to example embodiments of the present disclosure.

As shown in FIG. 1, a display device according to an example embodiment of the present disclosure may include a display panel 10, a timing controller 11, a data driver 12, a gate driver 13, and a power supply 20.

Although the case in which the timing controller 11, the data driver 12, and the power supply 20 are separately provided is shown, as an example, in FIG. 1, a part or all of the timing controller 11, the data driver 12, and the power supply 20 may be integrated into a driving integrated circuit. In FIG. 1, each of the data driver 12, the gate driver 13, and the power supply 20 may include a panel driving circuit configured to drive the display panel 10.

Although the case in which the gate driver 13 is provided separately from the display panel 10 is shown, as an example, in FIG. 1, the present disclosure is not limited thereto. The gate driver 13 may be provided in a non-active area NA of the display panel 10 and may be directly formed on a substrate of the display panel 10 in a gate-driver-in-panel (GIP) manner.

The display panel 10 may include an active area AA in addition to the non-active area NA.

The active area AA may be an area configured to display an image. A plurality of sub-pixels SP is disposed in the active area AA and, as such, an image may be displayed using the plurality of sub-pixels SP. An area in which the plurality of sub-pixels SP is disposed may become the active area AA, and the non-active area NA may be an area which surrounds the active area AA and is disposed at an outer edge of the display panel and in which no image is displayed.

The plurality of sub-pixels SP disposed in the active area AA may display, for example, different colors such as red (R), green (G), and blue (B). For example, the plurality of sub-pixels SP may include sub-pixels respectively configured to emit light of different colors.

The plurality of sub-pixels SP respectively configured to emit light of different colors may be grouped into one unit pixel UP.

When a pixel group for color expression is defined as a unit pixel UP, the unit pixel UP may be configured through inclusion of a plurality of sub-pixels SPR, SPG, and SPB configured to emit light of red (R), green (G), and blue (B) or may be configured through further inclusion of a sub-pixel configured to emit light of white (W) in addition to red (R), green (G), and blue (B). Each unit pixel UP may express various colors by mixing different colors emitted from a plurality of sub-pixels.

In FIG. 1, the case in which a unit pixel includes a red sub-pixel SPR configured to emit light of red, a green sub-pixel SPG configured to emit light of green, and a blue sub-pixel SPB configured to emit light of blue is shown as an example.

At least one panel driving circuit configured to drive the plurality of sub-pixels SP may be disposed in the non-active area NA.

The timing controller 11 may supply, to the data driver 12, digital image data D-DATA transmitted from a host system (not shown).

The timing controller 11 may receive timing signals, such as a vertical synchronization signal, a horizontal synchronization signal, a data enable signal, a dot clock signal, etc., from the host system and, as such, may generate timing control signals for control of operation timing of the panel driving circuit.

The timing control signals may include a gate timing control signal GDC for control of operation timing of the gate driver 13, a data timing control signal DDC for control of operation timing of the data driver 12, and a power timing control signal PDC for control of operation timing of the power supply 20.

The data driver 12 may be connected to the plurality of sub-pixels SP through data lines DL (DL1 to DLm). The data driver 12 may generate data voltages, which are analog signals required for driving of the plurality of sub-pixels SP, based on the digital image data D-DATA input from the timing controller 11, and may supply the data voltages to the data lines DL.

The data driver 12 may sample and latch the digital image data D-DATA based on the data timing control signal DDC input from the timing controller 11 to convert the digital image data D-DATA into parallel data.

The data driver 12 may subsequently convert the digital image data D-DATA into analog data voltages in accordance with gamma compensation voltages through a digital-analog converter (referred to as a “DAC” hereinafter), and may then supply the analog data voltages to the plurality of sub-pixels SP through the data lines DL, respectively. The analog data voltages may be analog voltage values of different voltage levels corresponding to image grayscales to be expressed at the plurality of sub-pixels SP.

The data driver 12 may output data voltages to the plurality of sub-pixels SP in accordance with the data timing control signal DDC. The data driver 12 may be constituted by a plurality of source driver integrated circuits. Each source driver integrated circuit may include a shift register, a latch, a level shifter, a DAC, and an output buffer.

The gate driver 13 may generate scan signals based on the gate timing control signal GDC, and may supply the scan signals to the plurality of sub-pixels SP through gate lines GL (GL1 to GLn), respectively.

The power supply 20 may generate a high-level drive voltage EVDD with a fixed level by processing input power in accordance with the power timing control signal PDC, and may supply the high-level drive voltage EVDD to the display panel 10.

As shown in circuit diagram (a) of FIG. 2, at least one of the plurality of sub-pixels SP may include, for example, a first switching transistor ST1, a driving transistor DT, a capacitor Cst, and a light emitting element OLED.

A first electrode (for example, a drain electrode) of the first switching transistor ST1 may be electrically connected to a data line DL, a second electrode (for example, a source electrode) of the first switching transistor ST1 may be electrically connected to a first node N1, and a gate electrode of the first switching transistor ST1 may be electrically connected to a gate line GL.

The first switching transistor ST1 may transmit, to the first node N1, a data signal supplied through the data line DL in response to a scan signal supplied through the gate line GL.

The capacitor Cst may be electrically connected to the first node N1 and, as such, may be charged with a voltage applied to the first node N1.

A first electrode (for example, a drain electrode) of the driving transistor DT may receive a high-level drive voltage EVDD, and a second electrode (for example, a source electrode) of the driving transistor DT may be electrically connected to a first electrode (for example, an anode) of the light emitting element OLED. The driving transistor DT may control a magnitude of drive current flowing through the light emitting element OLED, corresponding to a voltage applied to a gate electrode thereof.

The light emitting element OLED may output light corresponding to the drive current. The light emitting element OLED may output light corresponding to one of red (R), green (G), blue (B), and white (W).

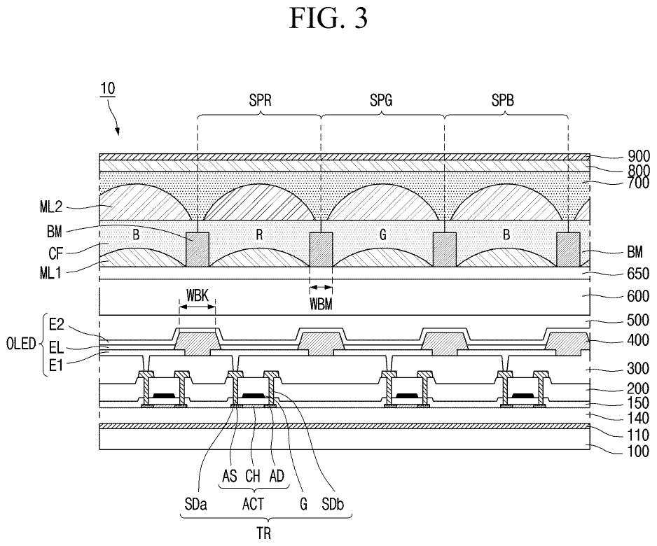

The light emitting element OLED may include the first electrode (for example, the anode designated by “E1” in FIG. 3), an emission layer (for example, “EL” in FIG. 3) disposed on the first electrode E1, and a second electrode (for example, a cathode designated by “E2” in FIG. 3) configured to supply a common voltage.

The display panel 10 of the present disclosure may have, for example, (1) a top emission type structure in which light generated from the light emitting element OLED is emitted to a top side of the display panel 10, (2) a bottom emission type structure in which light generated from the light emitting element OLED is emitted to a bottom side of the display panel 10, or (3) a dual emission type structure in which light generated from the light emitting element OLED is emitted to both the top and bottom sides of the display panel 10. When the display panel 10 has the top emission type structure as described above, the first electrode E1 may include a conductive material and may include a structure including a transparent conductive layer (not shown) and a reflective layer (not shown) stacked under the transparent conductive layer. The transparent conductive layer may be constituted by, for example, a transparent conductive oxide material such as indium tin oxide (ITO), indium zinc oxide (IZO), etc. The reflective layer may be constituted by, for example, silver (Ag), aluminum (Al), gold (Au), molybdenum (Mo), tungsten (W), chromium (Cr), an alloy thereof, or the like. Accordingly, the first electrode E1 may reflect light incident from a front surface thereof at which the emission layer EL is disposed, in accordance with high reflectance of the reflective layer.

The emission layer EL may generate light having a luminance corresponding to a voltage difference between the first electrode E1 and the second electrode E2. For example, the emission layer EL may include an emission material layer (EML) including an emission material. The emission material may include an organic material, an inorganic material, or a hybrid material. For example, the emission layer EL may include an emission material layer constituted by an organic material.

The emission layer EL may include at least one of a first common emission layer (not shown) disposed between the emission layer EL and the first electrode E1 or a second common emission layer (not shown) disposed between the emission layer EL and the second electrode E2. Each of the first common emission layer (not shown) and the second common emission layer (not shown) may include at least one of a hole injection layer (HIL), a hole transport layer (HTL), an electron transport layer (ETL), or an electron injection layer (EIL).

The second electrode E2 may include a conductive material. The second electrode E2 may include a material different from that of the first electrode E1. For example, the second electrode E2 may be a transparent electrode constituted by a transparent conductive material such as ITO or IZO. The second electrode E2 may have higher transmittance than that of the first electrode E1.

Although the second electrode E2 may be formed of, for example, a transparent metal oxide such as ITO or IZO, the present disclosure is not limited thereto. When the display device according to the embodiment of the present disclosure is of a top emission type, the second electrode E2 may be disposed using a translucent conductive material allowing transmission of light therethrough. For example, the second electrode E2 may be formed of at least one of LiF/Al, CsF/Al, Mg: Ag, Ca/Ag, Ca: Ag, LiF/Mg: Ag, LiF/Ca/Ag, and LiF/Ca: Ag alloys. In the display device according to the embodiment of the present disclosure, accordingly, light generated from the emission layer EL may be emitted to the top side of the display panel 10 as the light is reflected by the first electrode E1 and is then discharged through the second electrode E2.

When the display panel 10 has the bottom emission type structure, the first electrode E1 may be constituted by a transparent electrode including a transparent conductive material such as ITO or IZO or a translucent conductive material allowing transmission of light therethrough, and the second electrode E2 disposed over the emission layer EL may be configured through inclusion of a structure having a transparent conductive layer and a reflective layer stacked over the transparent conductive layer. In the display device according to the embodiment of the present disclosure, accordingly, light generated from the emission layer EL may be emitted to the bottom side of the display panel 10 as the light is reflected by the second electrode E2 and is then discharged through the first electrode E1.

On the other hand, when the display panel 10 has the dual emission type structure, each of the first electrode E1 and the second electrode E2 may be constituted by a transparent electrode including a transparent conductive material such as ITO or IZO or a translucent conductive material allowing transmission of light therethrough. Accordingly, light generated from the emission layer EL may be emitted to the top side of the display panel 10 as the light is discharged through the second electrode E2 or may be emitted to the bottom side of the display panel 10 as the light is discharged through the first electrode E1.

Although the case in which the driving transistor DT is directly connected to the light emitting element OLED is shown, as an example, in circuit diagram (a) of FIG. 2, the present disclosure is not limited thereto. As shown in circuit diagram (b) of FIG. 2, the driving transistor DT may be connected to the light emitting element OLED through a second switching transistor ST2.

In detail, as shown in circuit diagram (b) of FIG. 2, the second switching transistor ST2 may be disposed between the driving transistor DT and the light emitting element OLED, a first electrode of the second switching transistor ST2 may be connected to the driving transistor DT, and a second electrode of the second switching transistor ST2 may be electrically connected to the light emitting element OLED. The second switching transistor ST2 may control ON/OFF of drive current applied from the driving transistor DT to the light emitting element OLED in response to an emission signal applied to a gate electrode thereof.

In addition, although not shown in FIG. 2, a compensation circuit (not shown) configured to compensate a threshold voltage, etc. of the driving transistor DT may be further included in the sub-pixel SP. The compensation circuit may include at least one transistor connected to the driving transistor DT, and may be provided in the sub-pixel SP.

The compensation circuit may be configured in the sub-pixel SP to have various structures of 3T1C including three transistors and one capacitor, 4T2C including four transistors and two capacitors, 5T2C, 6T1C, 6T2C, 7T1C, 7T2C, 8T1C, etc. in accordance with configuration methods.

FIG. 3 is a cross-sectional view explaining an example of a cross-sectional structure applied to the display panel according to example embodiments of the present disclosure.

As shown in FIG. 3, the display panel 10 may include a substrate 100, an insulating layer 110, a buffer layer 140, a gate insulating layer 150, an interlayer insulating layer 200, a planarization layer 300, a bank 400, a light emitting element OLED, an encapsulation layer 500, an optical layer 600, an adhesive layer 650, a black matrix BM, a first lens ML1, a color filter CF, a second lens ML2, a high refractive index layer 700, a polarization plate 800, a cover layer 900, and a transistor TR.

In FIG. 3, the transistor TR may be one of the first switching transistor ST1, the second switching transistor ST2, and the driving transistor DT described with reference to FIG. 2. In FIG. 3, the case in which the transistor TR is the driving transistor DT shown in circuit diagram (a) of FIG. 2 is shown as an example. The display device cross-sectional structure of FIG. 3 is an example for understanding of the present disclosure and, as such, the present disclosure is not limited thereto.

The substrate 100 may be formed of a plastic material having flexibility and, as such, may have flexible characteristics. The substrate 100 may also include a thin glass material having flexibility.

The insulating layer 110 may be disposed on an active area AA and a non-active area NA on the substrate 100. The insulating layer 110 may be disposed on the substrate 100 to protect structures on the substrate 100 vulnerable to moisture penetrating through the substrate 100. The insulating layer 110 may include one or more of a silicon oxide (SiOₓ) layer, a silicon nitride (SiNₓ) layer, and a silicon oxynitride (SiOₓN_{y}) layer.

The buffer layer 140 may be provided on the insulating layer 110. The buffer layer 140 may include an inorganic insulating material such as silicon oxide (SiO) or silicon nitride (SiN).

The transistor TR may be disposed on the buffer layer 140. The transistor TR may include a gate electrode G, an active layer ACT, and first and second source-drain electrodes SDa and SDb. The active layer ACT may include a source region AS, a channel region CH, and a drain region AD. The source region AS and the drain region AD may have higher electrical conductivity than that of the channel region CH. The channel region CH may form a channel in response to a voltage applied to the gate electrode G.

The gate insulating layer 150 may be stacked on the buffer layer 140 to cover the active layer ACT. The gate insulating layer 150 may insulate the gate electrode G and the active layer ACT of the transistor TR from each other.

The interlayer insulating layer 200 may be disposed on the gate insulating layer 150 to cover the gate electrode G of the transistor TR. The first and second source-drain electrodes SDa and SDb of the transistor TR may be disposed on the interlayer insulating layer 200.

The first and second source-drain electrodes SDa and SDb of the transistor TR may extend through the interlayer insulating layer 200 and the gate insulating layer 150 to contact the source region and the drain region of the transistor TR.

The planarization layer 300 may be stacked on the interlayer insulating layer 200 to cover the first and second source-drain electrodes SDa and SDb of the transistor TR. The planarization layer 300 may remove a step caused by a driving circuit, and may have a flat surface at an upper surface thereof. The planarization layer 300 may include an insulating material having high flowability.

One electrode of the first and second source-drain electrodes SDa and SDb of the transistor TR may extend through the planarization layer 300 to contact a first electrode E1 of the light emitting element OLED.

The bank 400 may be disposed on the planarization layer 300. The bank 400 may define an emission area of each sub-pixel, and areas of respective sub-pixels may be partitioned from one another by corresponding portions of the bank 400.

The bank 400 may include a light absorption material. For example, the bank 400 may include a black pigment such as carbon black. Accordingly, the bank 400 may minimize or reduce reflectance through absorption of external light, may achieve an enhancement in black color, and may achieve an enhancement in picture quality through improvement of a contrast ratio and color accuracy.

The bank 400 may include an organic insulating material. The bank 400 may cover an edge of the first electrode E1 (for example, an anode). An emission layer EL and a second electrode E2 (for example, a cathode) may be stacked on a portion of the first electrode E1 exposed by the bank 400.

Accordingly, respective areas of a plurality of sub-pixels SPR, SPG, and SPB defined by respective emission areas may be partitioned from one another by corresponding portions of the bank 400. The light emitting element OLED may be disposed in each emission area. The light emitting element OLED may include the first electrode E1, the emission layer EL, and the second electrode E2.

The first electrode E1 may function as, for example, an anode, and may include a conductive material. The first electrode E1 may have high reflectance. For example, the first electrode E1 may include a metal such as aluminum (Al) or silver (Ag).

The emission layer EL may generate light having luminance corresponding to a voltage difference between the first electrode E1 and the second electrode E2. For example, the emission layer EL may include an emission material layer (EML) including an emission material. The emission material may include an organic material, an inorganic material, or a hybrid material. For example, the emission layer EL may include an emission material layer constituted by an organic material.

The second electrode E2 may function as, for example, a cathode, and may include a conductive material. The second electrode E2 may include a material different from that of the first electrode E1. For example, the second electrode E2 may be a transparent electrode constituted by a transparent conductive material such as ITO or IZO. The second electrode E2 may have higher transmittance than that of the first electrode E1.

The encapsulation layer 500 may be disposed on the second electrode E2 of light emitting elements OLED, and may perform an encapsulation function for preventing or suppressing damage to light emitting elements OLED caused by external impact and moisture.

The encapsulation layer 500 may be configured through alternate stacking of an inorganic insulating material layer and an organic insulating material layer.

A step caused by the light emitting element OLED may be removed by the encapsulation layer 500, and an upper surface of the encapsulation layer 500 may be a flat surface.

The optical layer 600 may be disposed on the encapsulation layer 500. The optical layer 600 may form an upper surface and, as such, may function as an optical gap configured to induce uniform light refraction through a lens and, as such, to enhance light extraction efficiency. For this function, the optical layer 600 may have a lower refractive index than that of the second lens ML2.

The optical layer 600 may include glass or a polymer material (polycaprolactone (PCL)). When the optical layer 600 includes a polymer material (PCL), the polymer material (PCL) may be selected from an acrylic resin, a phenolic resin, a polyimide resin, polyamide resin, an unsaturated polyester resin, a polyphenylene resin, a polyphenylene sulfide resin, benzocyclobutene, etc. In this case, the refractive index of the optical layer 600 may be lower than the refractive index of the first lens ML1.

The adhesive layer 650 may be disposed on the optical layer 600 to attach the optical layer 600 under the first lens ML1 and the black matrix BM. The adhesive layer 650 may include an insulating material having high flowability and an adhesive material. For example, the adhesive layer 650 may include a flowable material identical to that of the planarization layer 300. The adhesive layer 650 may have a lower refractive index than that of the second lens ML2 and may have a refractive index substantially equal to that of the optical layer 600.

The black matrix BM may be disposed on the adhesive layer 650. The black matrix BM may include a light absorption material and may include, for example, a black pigment. The black matrix BM may overlap with the bank 400. The black matrix BM defines an opening corresponding to the each of the sub-pixels.

The first lens ML1 may be disposed in openings of the black matrix BM. In other words, the first lens ML1 may be disposed at a space between the black matrix BM adjacent to each other. For example, a bottom surface of the first lens ML1 may be disposed on the adhesive layer 650, and the black matrix BM may be disposed at opposite sides of the first lens ML1.

The first lens ML1 may function as a convex lens and, as such, may prevent the width of external light incident from the second lens ML2 from increasing excessively by suppressing the width of the external light. The first lens ML1 may have a high refractive index and may include a polyimide-acrylic composite (PAC).

The color filter CF may be disposed on the first lens ML1 in each opening of the black matrix BM. For example, the color filter CF may fill a space between the black matrix BM and the first lens ML1, and a portion of the color filter CF may be disposed to cover a portion of an upper surface of the black matrix BM.

The color filter CF may include a colorant and a pigment representing a color identical to a color emitted from the emission layer of each sub-pixel. For example, the red sub-pixel SPR may include a red color filter R expressing a color identical to red emitted from the emission layer of the red sub-pixel SPR, the green sub-pixel SPG may include a green color filter G, and the blue sub-pixel SPG may include a blue color filter B.

The second lens ML2 may be disposed on the color filter CF. For example, the second lens ML2 may be disposed on the color filter CF such that a bottom surface thereof covers each opening of the black matrix BM. The second lens ML2 may have a low refractive index and may include a polyimide-acrylic composite (PAC).

The second lens ML2 may be configured to provide a dome shape to the high refractive index layer 700 such that the high refractive index layer 700 functions as a concave lens. That is, an interface of the high refractive index layer 700 contacting the second lens ML2 may have a concave dome shape in accordance with a shape of an upper surface of the second lens ML2, and the concave dome shape may function as a concave lens.

The high refractive index layer 700 may be disposed on the second lens ML2. For example, the high refractive index layer 700 may be disposed on a plurality of second lenses ML2 spaced apart from one another in a horizontal direction while filling spaces among the plurality of second lenses ML2. The high refractive index layer 700 may have a high refractive index and may include a polyimide-acrylic composite (PAC).

The interface of the high refractive index layer 700 contacting the second lens ML2 may have a concave curved surface shape and may function as a concave lens configured to increase a width of external light incident from an exterior. That is, the interface of the high refractive index layer 700 contacting the second lens ML2 may increase the width of external light incident from the exterior and, as such, the width-increased light may then be incident upon the first lens ML1.

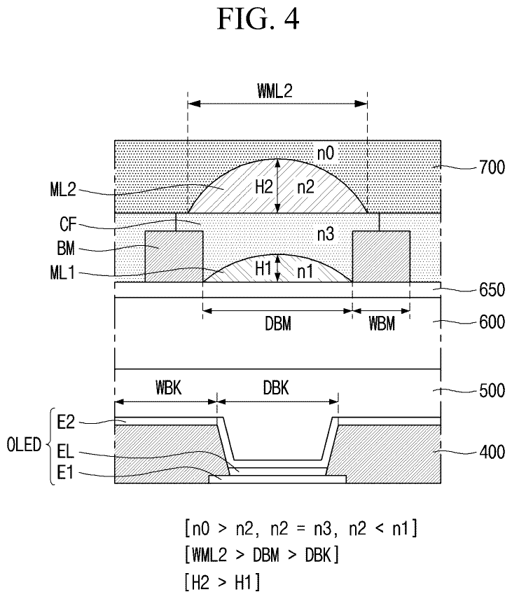

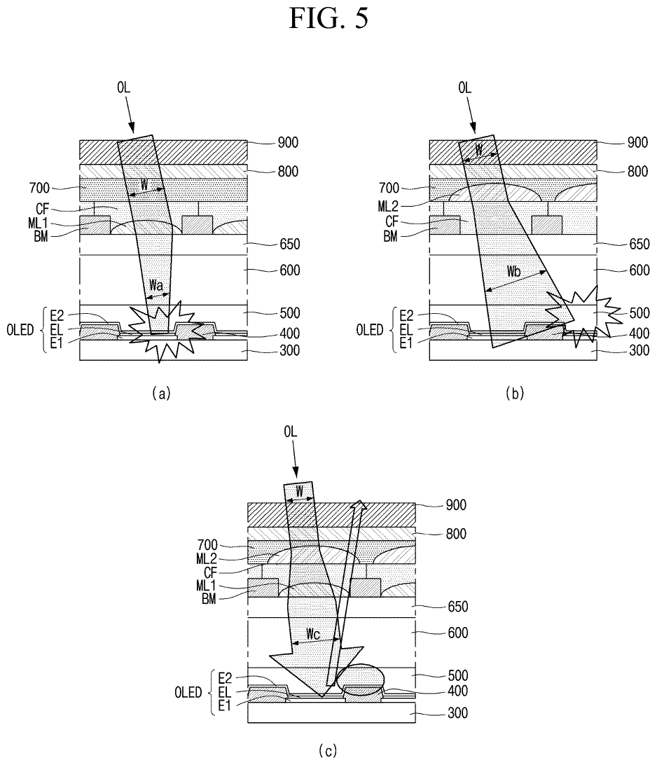

An optical structure including the first lens ML1, the color filter CF, the second lens ML2, and the high refractive index layer 700 will be described in more detail with reference to FIGS. 4 and 5 after description of the remaining constituent elements shown in FIG. 3.

The polarization plate 800 may be disposed on the high refractive index layer 700 and may reduce reflection of external light. The cover layer 900 may be disposed on the polarization plate 800 and may include a glass made of a light-transmitting material.

The display panel 10 as described above may increase the width of external light incident from the exterior to reduce an optical density of the incident external light and may control the width increase within an appropriate range such that, when the width-increased external light is incident upon the subject sub-pixel, the width-increased external light is not reflected by the first electrode of the sub-pixel adjacent to the subject sub-pixel and a part of the width-increased external light is absorbed by the bank 400. Thus, it may be possible to reduce the reflectance of the display panel 10.

Hereinafter, the optical structure including the first lens ML1, the color filter CF, the second lens ML2 and the high refractive index layer 700, and effects thereof will be described with reference to FIGS. 4 and 5.

FIG. 4 is a cross-sectional view explaining structures of the first and second lenses of each sub-pixel shown in FIG. 3 in more detail.

For convenience of description, the structure from the light emitting element to the high refractive index layer 700 in a part of sub-pixels of the display panel shown in FIG. 3 is shown in a width-increased state in FIG. 4.

In FIG. 4, the high refractive index layer 700 may have a high refractive index, the first lens ML1 and the color filter CP may have low refractive indexes, respectively, and the second lens ML2 may have a high refractive index. In detail, the refractive index of the high refractive index layer 700 may be higher than the refractive index of the second lens ML2, and the refractive index of the first lens ML1 may he higher than the refractive index of the second lens ML2. In FIG. 4, the refractive index of the high refractive index layer 700 is represented by “n0”, the refractive index of the second lens ML2 is represented by “n2”, the refractive index of the first lens ML1 is represented by “n1”, and the refractive index of the color filter CF is represented by “n3”.

Accordingly, the width of external light may be increased at the interface between the high refractive index layer 700 and the second lens ML2, the increased width of the external light may be appropriately controlled as the external light passes through the second lens ML2, and a part of the external light may be absorbed by the bank 400. Thus, it may be possible to reduce the reflectance of the display panel 10.

The refractive index difference between the high refractive index layer 700 and the second lens ML2, n0−n2, may be greater than the refractive index difference between the second lens ML2 and the color filter CF, n2−n3, and the refractive index difference between the first lens ML1 and the color filter CF, n1−n3, may be greater than the refractive index difference between the second lens ML2 and the color filter CF, n2−n3. Accordingly, the width of the external light increased as the external light passes through the interface between the high refractive index layer 700 and the second lens ML2 may be appropriately controlled to be a uniform width without being increased as the external light passes through the second lens ML2.

The refractive index n2 of the second lens ML2 may be equal to the refractive index n3 of the color filter CF. In this case, accordingly, the width of the external light increased as the external light passes through the interface between the high refractive index layer 700 and the second lens ML2 may be continuously increased until the external light reaches the first lens ML1.

The refractive index n0 of the high refractive index layer 700 and the refractive index n1 of the first lens ML1 may be equal, and the refractive index difference n0−n2 between the high refractive index layer 700 and the second lens ML2 may be substantially equal to the refractive index difference n1−n3 between the first lens ML1 and the color filter CF. Accordingly, although the width of the external light is continuously increased as the external light passes through the interface between the high refractive index layer 700 and the second lens ML2, the width increase of the external light is limited as the external light passes through the first lens ML1 and, as such, the external light maintains a uniform width.

A width WML2 of the second lens ML2 may be greater than the width of the first lens ML1. For example, the width WML2 of the second lens ML2 may be greater than an opening width DBM of the black matrix BM. That is, an end of the second lens ML2 may overlap with the black matrix BM. The width of the first lens ML1 may be equal to or smaller than the opening width DBM of the black matrix BM.

A distance DBK among the portions of the bank 400 partitioning the emission areas of adjacent sub-pixels from one another may be smaller than the opening width DBM of the black matrix BM. A width WBK of the bank 400 may be greater than a width WBM of the black matrix BM. Accordingly, it may be possible to increase an area in which external light is absorbed by the bank 400.

A maximum height H2 of the second lens ML2 may be greater than a maximum height H1 of the first lens ML1, and the radius of curvature of the second lens ML2 may be greater than the radius of curvature of the first lens ML1. Accordingly, the width increase of external light occurring as the external light passes through the second lens ML2 may be further increased, and reflectance of the external light may be further reduced.

FIG. 5 shows cross-sectional views explaining effects of the first and second lenses applied to example embodiments the present disclosure.

The cross-sectional view (a) of FIG. 5 is a comparative example in which the second lens ML2 are omitted from an upper side of the color filter CF, and only the first lens ML1 is provided, cross-sectional view (b) of FIG. 5 is a comparative example in which the first lens ML1 is omitted from a lower side of the color filter CF, and only the high refractive index layer 700 and the second lens ML2 are provided at the upper side of the color filter CF, and cross-sectional view (c) of FIG. 5 is an example of the present disclosure identical to FIG. 4.

As shown in cross-sectional view (a) of FIG. 5, in the comparative example in which the second lens ML2 are omitted from the upper side of the color filter CF, and only the first lens ML1 is provided, external light OL incident from an exterior and having a width of W may be continuously reduced in width as the external light passes through the first lens ML1. As a result, the external light may have a width Wa smaller than the width W when the external light is incident upon the first electrode E1 of the light emitting element OLED.

In this case, although the area of the external light OL reflected by the first electrode E1 of the light emitting element OLED may be reduced, the optical density of the external light may be rather increased and, as such, the intensity of the light may be increased. As a result, when the external light OL is reflected by the first electrode E1, the reflectance thereof may be rather increased due to strong intensity of the light.

In addition, as shown in cross-sectional view (b) of FIG. 5, in the comparative example in which the first lens ML1 is omitted from the lower side of the color filter CF, and only the high refractive index layer 700 and the second lens ML2 are provided at the upper side of the color filter CF, external light OL incident from an exterior and having a width of W may be continuously increased in width as the external light is refracted at the interface between the high refractive index layer 700 and the second lens ML2, and may have a width Wb greater than the width W when the external light passes through the optical layer 600.

In this case, although the intensity of the external light may be reduced as the width of the external light OL is increased from W to Wb and, as such, the optical density of the external light is reduced, the width of the external light OL may be excessively increased as the external light OL passes through the color filter CF and the optical layer 600. As a result, the external light OL may penetrate even the adjacent sub-pixel and may be reflected by the first electrode E1 provided at the light emitting element OLED of the adjacent sub-pixel.

As a result, the reflectance of the external light OL may be rather increased. The external light OL, which passes through the optical filter of a particular color (for example, R) may be reflected by a light emitting element configured to emit another color (for example, G) and, as such, color mixing may occur. Due to such color mixing, the visual perception of the reflection of light may be varied or degraded.

However, in the present disclosure, as shown in cross-sectional view (c) of FIG. 5, external light OL incident from an exterior and having a width of W may be increased in width as the external light OL passes through the interface between the high refractive index layer 700 and the second lens ML2. The external light OL may then be refracted as the external light OL passes through the first lens ML1 and, as such, the width increase thereof may be limited. Accordingly, the external light OL may be incident upon the light emitting element OLED in a state of having a uniform width Wc.

In this case, the external light OL may not penetrate even the sub-pixel adjacent to the subject sub-pixel by virtue of the limited width thereof, and a part of the external light OL may be absorbed by the bank 400. The external light OL reflected by the first electrode EL provided at the light emitting element OLED of the subject sub-pixel may be reflected in a state of having a relatively low optical density and a relatively low intensity. Accordingly, the intensity of the reflected external light OL may also be reduced.

As apparent from the above description, in the embodiment of the present disclosure, first and second lenses having different refractive indexes are provided at upper and lower sides of a color filter provided in openings of a black matrix and, as such, it may be possible to increase the width of incident external light and to absorb the width-increased external light by a bank. Accordingly, the reflectance of the external light may be reduced.

While the present disclosure has been particularly shown and described with reference to example embodiments, those skilled in the art will appreciate, through the above-described content, that various modifications, additions, and substitutions are possible, without departing from the scope and spirit of the disclosure. Therefore, the technical scope of the present disclosure may be defined by the appended claims and their equivalents without being limited to the content described in the detailed description of the present disclosure.

What is claimed is:

1. A display panel, comprising:
a substrate including an active area with a plurality of sub-pixels and a non-active area;
a black matrix defining an opening corresponding to each of the plurality of sub-pixels;
a first lens disposed in the opening;
a color filter disposed on the first lens in the opening;
a second lens disposed on the color filter; and
a high refractive index layer disposed on the second lens,
wherein a refractive index of the first lens is higher than a refractive index of the second lens, and
wherein a refractive index of the high refractive index layer is higher than the refractive index of the second lens.

2. The display panel according to claim 1, wherein a refractive index difference between the first lens and the color filter is greater than a refractive index difference between the second lens and the color filter.

3. The display panel according to claim 1, wherein a refractive index difference between the high refractive index layer and the second lens is greater than a refractive index difference between the second lens and the color filter.

4. The display panel according to claim 1, wherein the refractive index of the second lens is equal to a refractive index of the color filter.

5. The display panel according to claim 1, wherein the refractive index of the high refractive index layer is equal to a refractive index of the first lens, and a refractive index difference between the high refractive index layer and the second lens is equal to a refractive index difference between the first lens and the color filter.

6. The display panel according to claim 1, wherein a width of the second lens is greater than a width of the first lens.

7. The display panel according to claim 1, further comprising:
a light emitting element in one of the plurality of sub-pixels and including a first electrode, an emission layer disposed on the first electrode, and a second electrode disposed on the emission layer; and
a bank covering an edge of the first electrode and partitioning emission areas of adjacent sub-pixels.

8. The display panel according to claim 7, wherein a distance among portions of the bank partitioning the emission areas of the adjacent sub-pixels is smaller than a width of the opening.

9. The display panel according to claim 7, wherein the bank comprises a light absorption material.

10. The display panel according to claim 7, wherein a width of the bank is greater than a width of the black matrix.

11. The display panel according to claim 1, wherein a radius of curvature of the second lens is greater than a radius of curvature of the first lens.

12. The display panel according to claim 1, wherein a maximum height of the second lens is greater than a maximum height of the first lens.

13. The display panel according to claim 7, wherein the black matrix and the first lens are disposed on an optical layer disposed over the light emitting element.

14. The display panel according to claim 13, wherein a refractive index of the optical layer is lower than the refractive index of the first lens.

15. The display panel according to claim 12, wherein an interface of the high refractive index layer contacting the second lens has a concave curved surface shape.
